(19) United States
(12) Patent Application Publication
(10) Pub. No.: US 2026/0190574 A1
(43) Pub. Date: Jul. 2, 2026

(54) DISPLAY APPARATUS

(71) Applicant: AUO Corporation, Hsinchu City (TW)

(72) Inventors: Kuan-Lin Chiu, Hsinchu City (TW); Han-Chung Lai, Hsinchu City (TW); Ming-Chi Hsu, Hsinchu City (TW); Cheng-Han Chung, Hsinchu City (TW)

(73) Assignee: AUO Corporation, Hsinchu City (TW)

(21) Appl. No.: 19/248,472

(22) Filed: Jun. 25, 2025

(30) Foreign Application Priority Data
Dec. 30, 2024 (TW) 113151522

(51) Int. Cl. H10H 29/49

(52) U.S. Cl. CPC H10H 29/49

(57) ABSTRACT

A display apparatus including pixel structures is provided. Each of the pixel structures includes pad groups, light-emitting elements, a first metal element and a second metal element. Each of the pad groups includes a pad. The light-emitting elements are respectively bonded to the pad groups. The first metal element and the second metal element are disposed outside the pad groups and staggered with each other. A line width of the first metal element is greater than a line width of the second metal element. The first metal element extends in a first direction, and a long side of the pad intersects with the first direction.

### CROSS-REFERENCE TO RELATED APPLICATION

This application claims the priority benefit of Taiwan application serial no. 113151522, filed on Dec. 30, 2024. The entirety of the above-mentioned patent application is hereby incorporated by reference herein and made a part of this specification.

### BACKGROUND

### Technical Field

The disclosure relates to a display apparatus.

### Description of Related Art

A light-emitting diode display panel includes an active element substrate and a plurality of light-emitting diode elements transferred onto the active element substrate. Inheriting the characteristics of the light-emitting diode, the light-emitting diode display panel has advantages such as power saving, high efficiency, high brightness, and fast response time. In addition, compared with an organic light-emitting diode display panel, the light-emitting diode display panel also has advantages such as easy color adjustment, long light-emitting lifetime, and no image retention. Therefore, the light-emitting diode display panel is regarded as the next-generation display technology. However, when a laser bonding process is used to bond the light-emitting diode and the active element substrate, due to different distributions of a metal layer near the pad, an issue of uneven bonding strength between the pad and solder often occurs.

### SUMMARY

The disclosure provides a display apparatus to improve the issue of uneven bonding strength between pads and solder.

According to an embodiment of the disclosure, a display apparatus includes a substrate and a plurality of pixel structures. The plurality of pixel structures are disposed on the substrate. Each of the plurality of pixel structures includes a plurality of pad groups, a plurality of light-emitting elements, a first metal element, and a second metal element. Each of the plurality of pad groups includes at least one pad. The plurality of light-emitting elements are respectively bonded to the plurality of pad groups. The first metal element and the second metal element are disposed outside the plurality of pad groups and are staggered with each other. A line width of the first metal element is greater than a line width of the second metal element. The first metal element extends in a first direction, and a long side of the at least one pad intersects with the first direction.

According to an embodiment of the disclosure, a display apparatus includes a substrate and a plurality of pixel structures. The plurality of pixel structures are disposed on the substrate. Each of the plurality of pixel structures includes a plurality of pad groups, a plurality of light-emitting elements, a first metal element, and a second metal element. Each of the plurality of pad groups includes a first pad and a second pad. The plurality of light-emitting elements are respectively bonded to the plurality of pad groups. The first metal element and the second metal element are disposed outside the plurality of pad groups and are staggered with each other. A line width of the first metal element is greater than a line width of the second metal element. The second metal element extends in a second direction. The first direction intersects with the second direction. A geometric center of the first pad has a first distance from the first metal element in the second direction. A geometric center of the second pad has a second distance from the first metal element in the second direction. A difference value between the first distance and the second distance is less than a width of the first pad in the first direction.

### BRIEF DESCRIPTION OF THE DRAWINGS

FIG. 1 is a top schematic view of a display apparatus according to an embodiment of the disclosure.

FIG. 2 is a cross-sectional schematic view of the display apparatus according to an embodiment of the disclosure.

FIG. 3 is a top and enlarged schematic view of a first metal element, a second metal element, and a pad group of a pixel structure according to an embodiment of the disclosure.

### DESCRIPTION OF THE EMBODIMENTS

Reference will now be made in detail to the exemplary embodiments of the disclosure, examples of which are illustrated in the accompanying drawings. Wherever possible, the same reference numbers are used in the drawings and the description to refer to the same or like parts.

It should be understood that when an element such as a layer, film, region, or substrate is referred to as being “on” or “connected to” another element, it can be directly on or connected to the other element, or Intermediate elements may also be present. In contrast, when an element is referred to as being “directly on” or “directly connected to” another element, there are no intervening elements. As used herein, “connection” can refer to physical and/or electrical connection. Furthermore, “electrical connection” or “coupling” can mean that there are other elements between two elements.

As used herein, “about”, “approximately”, or “substantially” includes the stated value and the average value within the acceptable deviation range of the specific value determined by a person of ordinary skill in the art, taking into account the measurement in question and a certain amount of measurement-related error (i.e., the limitation of the measurement system). For example, “about” can mean within one or more standard deviations of the stated value, or within ±30%, ±20%, ±10%, ±5%. Furthermore, “about”, “approximate” or “substantially” used herein can be based on optical properties, etching properties or other properties to select a more acceptable range of deviation or standard deviation, and not one standard deviation can be applied to all properties.

Unless otherwise defined, all terms (including technical and scientific terms) used herein have the same meaning as commonly understood by those of ordinary skill in the art to which the disclosure belongs. It will be further understood that terms such as those defined in commonly used dictionaries should be interpreted as having meanings consistent with the relevant art and the background or context of the disclosure, and should not be interpreted in an idealized or overly formal way, unless otherwise defined in the embodiments of the disclosure.

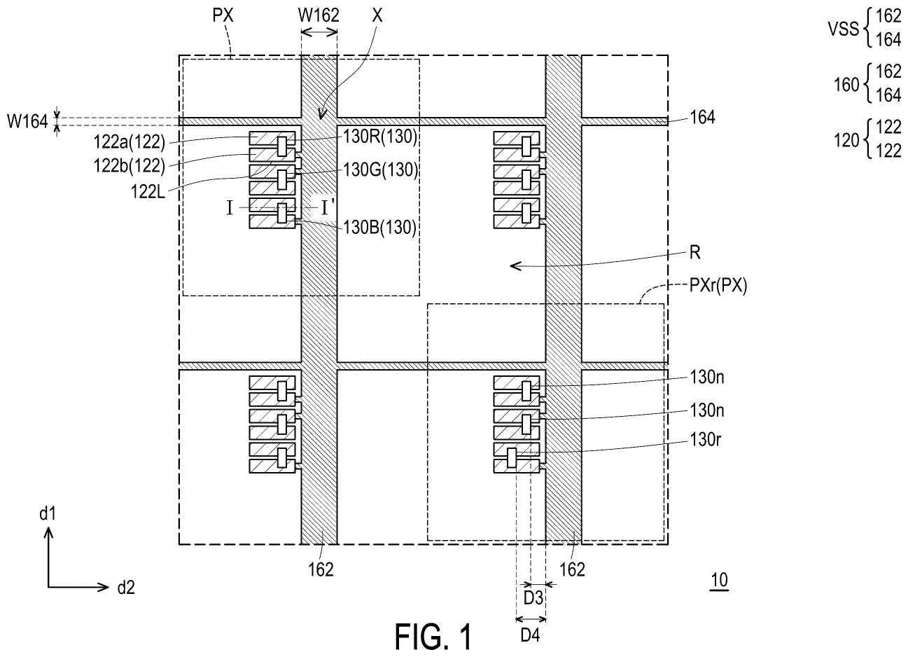

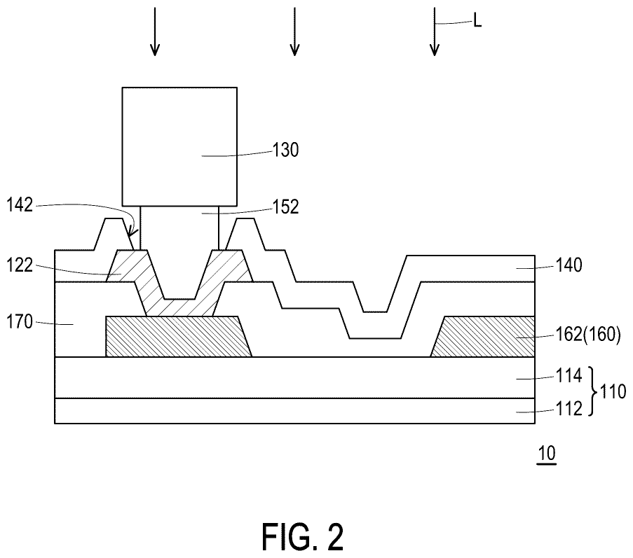

FIG. 1 is a top schematic view of a display apparatus according to an embodiment of the disclosure. FIG. 2 is a cross-sectional schematic view of the display apparatus according to an embodiment of the disclosure. FIG. 2 corresponds to section line I-I′ of FIG. 1.

Referring to FIG. 1 and FIG. 2, a display apparatus 10 includes a substrate 110 and a plurality of pixel structures PX disposed on the substrate 110. The substrate 110 includes a carrier base 112 and a driving circuit layer 114 disposed on the carrier base 112, and the plurality of pixel structures PX are electrically connected to the driving circuit layer 114 of the substrate 110.

Each of the pixel structures PX includes a plurality of pad groups 120, wherein each of the pad groups 120 includes at least one pad 122. In some embodiments, each of the pad groups 120 may include a plurality of pads 122 that are structurally separated, wherein one of the pads 122 is electrically connected to a sub-pixel driving circuit (not shown) of the driving circuit layer 114, and another pad 122 may be electrically connected to a common electrode VSS of the display apparatus 10, but the disclosure is not limited thereto. In some embodiments, a material of the pad 122 may be metal, alloy, or a combination thereof, but the disclosure is not limited thereto.

Each of the pixel structures PX further includes a plurality of light-emitting elements 130 respectively bonded to the plurality of pad groups 120. In some embodiments, each of the light-emitting elements 130 has a plurality of electrodes (not shown). The plurality of electrodes (not shown) of each of the light-emitting elements 130 are respectively electrically connected to the plurality of pads 122 of a corresponding one of the pad groups 120.

Specifically, in some embodiments, the pixel structure PX further includes an insulating layer 140 disposed on the pads 122. The insulating layer 140 has a plurality of openings 142 respectively overlapping the plurality of pads 122. The plurality of electrodes (not shown) of the light-emitting elements 130 may be respectively electrically connected to the plurality of pads 122 through a plurality of solders 152 (for example, but are not limited to, tin) located in the plurality of openings 142. In some embodiments, a laser bonding process may be used to bond the light-emitting elements 130 and the pad groups 120. In some embodiments, a material of the insulating layer 140 may be an inorganic material (for example, silicon oxide, silicon nitride, silicon oxynitride, or a stacked layer of at least two of the above materials), an organic material, or a combination of the above.

For example, in some embodiments, the plurality of light-emitting elements 130 of the pixel structure PX may include a first light-emitting element 130R, a second light-emitting element 130G, and a third light-emitting element 130B, wherein the first light-emitting element 130R, the second light-emitting element 130G, and the third light-emitting element 130B are respectively used to emit a first color light, a second color light, and a third color light that are different from one another. In some embodiments, the first color light, the second color light, and the third color light are, for example, red light, green light, and blue light respectively, but the disclosure is not limited thereto. In an embodiment, a light-emitting element 130 is, for example, a micro light-emitting diode (μLED), but the disclosure is not limited thereto.

Each of the pixel structures PX further includes a first metal element 162 and a second metal element 164. A line width W162 of the first metal element 162 is greater than a line width W164 of the second metal element 164. The first metal element 162 and the second metal element 164 are disposed outside the plurality of pad groups 120 and are staggered with each other. The first metal element 162 extends in a first direction d1. The second metal element 164 extends in a second direction d2. The first direction d1 and the second direction d2 intersect with each other. In some embodiments, the first direction d1 and the second direction d2 may optionally be perpendicular, but the disclosure is not limited thereto.

In some embodiments, the first metal element 162 and the second metal element 164 are disposed on the substrate 110. The pixel structure PX further includes an insulating layer 170. The insulating layer 170 covers the first metal element 162, and the pad 122 is disposed on the insulating layer 170. In some embodiments, a material of the insulating layer 170 may be an inorganic material (for example, silicon oxide, silicon nitride, silicon oxynitride, or a stacked layer of at least two of the above materials), an organic material, or a combination of the above.

In some embodiments, the first metal element 162 and the second metal element 164 may belong to at least one metal layer below the pad 122. In some embodiments, the first metal element 162 and the second metal element 164 are located outside an area occupied by the light-emitting element 130 and the pad 122 and are not covered by the light-emitting element 130 and the pad 122. When a laser bonding process is used to bond the light-emitting element 130 and the pad 122, a laser L may be directly absorbed by the first metal element 162 and/or the second metal element 164. In some embodiments, the first metal element 162 and the second metal element 164 may optionally belong to a same metal layer 160. The first metal element 162 and the second metal element 164 may intersect and have the same potential. For example, in some embodiments, the first metal element 162 and the second metal element 164 may have a same common potential, and the first metal element 162 and the second metal element 164 may form a common electrode VSS. However, the disclosure is not limited thereto. In other embodiments, the first metal element 162 and the second metal element 164 may optionally belong to different metal layers, and the first metal element 162 and the second metal element 164 do not necessarily have the same potential.

In some embodiments, the first metal element 162 of each of the pixel structures PX may be connected to the first metal element 162 of an adjacent one of the pixel structures PX. The second metal element 164 of each of the pixel structures PX may be connected to the second metal element 164 of an adjacent one of the pixel structures PX. The plurality of first metal elements 162 and the plurality of second metal elements 164 of the plurality of adjacent pixel structures PX may enclose a region R. An area in the region R that is not occupied by the pad 122 and the light-emitting element 130 may form a penetration area of the display apparatus 10. In some embodiments, the display apparatus 10 may be a transparent display, but the disclosure is not limited thereto.

A long side 122L of the pad 122 of each of the pad groups 120 intersects with the first direction d1. In some embodiments, the long side 122L of the pad 122 may be substantially perpendicular to the first metal element 162, and the long side 122L of the pad 122 may be substantially parallel to the second metal element 164, but the disclosure is not limited thereto. In some embodiments, the plurality of pads 122 of the plurality of pad groups 120 may be arranged along an extending direction of the first metal element 162, that is, the first direction d1. In some embodiments, the plurality of long sides 122L of the plurality of pads 122 of the plurality of pad groups 120 may be substantially parallel, but the disclosure is not limited thereto.

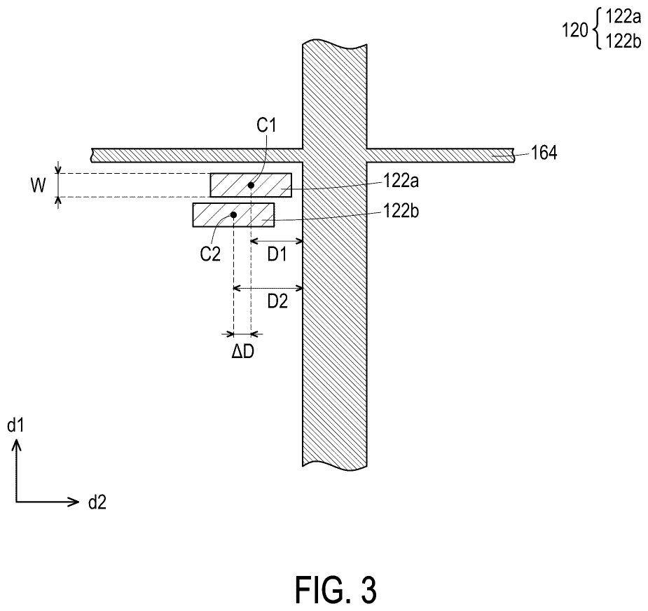

FIG. 3 is a top and enlarged schematic view of a first metal element, a second metal element, and a pad group of a pixel structure according to an embodiment of the disclosure. Referring to FIG. 3, in some embodiments, each of the pad groups 120 includes a first pad 122a and a second pad 122b. A geometric center C1 of the first pad 122a has a first distance D1 from the first metal element 162 in the second direction d2. A geometric center C2 of the second pad 122b has a second distance D2 from the first metal element 162 in the second direction d2. A difference value ΔD between the first distance D1 and the second distance D2 is less than a width W of the first pad 122a in the first direction d1. That is, the multiple distances from the multiple pads 122 bonded to a same light-emitting element 130 to the thicker first metal element 162 are equal or close. Accordingly, when a light-emitting element 130 is bonded to the plurality of pads 122 by using a laser bonding process, an influence of the thicker first metal element 162 on the plurality of solders 152 on the plurality of pads 122 can be the same or similar, thereby improving the issue of uneven bonding strength between the plurality of pads 122 and the light-emitting element 130 of a same pad group 120. According to a simulated structure, in a laser bonding process, a temperature difference of the plurality of pads of a same pad group of a conventional display apparatus is 32° C., while a temperature difference of the plurality of pads 122 of a same pad group 120 of the display apparatus 10 of the present embodiment can be reduced to 3° C.

Referring to FIG. 1 and FIG. 2, in some embodiments, an absorption rate of the second light-emitting element 130G for a laser L is greater than an absorption rate of the first light-emitting element 130R for the laser L, and the second light-emitting element 130G is farther from an intersection X of the first metal element 162 and the second metal element 164 than the first light-emitting element 130R. In some embodiments, an absorption rate of the third light-emitting element 130B for the laser L is greater than the absorption rate of the second light-emitting element 130G for the laser L, and the third light-emitting element 130B is farther from the intersection X of the first metal element 162 and the second metal element 164 than the second light-emitting element 130G. That is, in some embodiments, the greater the absorption rate of the light-emitting element 130 for the laser L, the farther the light-emitting element 130 is from the intersection X of the first metal element 162 and the second metal element 164. Accordingly, the issue of uneven bonding strength between the plurality of light-emitting elements 130 and the plurality of pad groups 120 can be improved. According to a simulated structure, in a laser bonding process, a temperature difference of the plurality of pad groups of a same pixel structure of a conventional display apparatus is 45° C., while a temperature difference of the plurality of pad groups 120 of a same pixel structure PX of the display apparatus 10 of the present embodiment can be reduced to 22° C.

The laser L refers to a laser beam used in a laser bonding process. For example, in some embodiments, a center wavelength of the laser L is 980 nm. The third light-emitting element 130B, which has the highest absorption rate for the laser L, may be a light-emitting element used to emit a blue light. The second light-emitting element 130G, which has a medium absorption rate for the laser L, may be a light-emitting element used to emit a green light. The first light-emitting element 130R, which has the lowest absorption rate for the laser L, may be a light-emitting element used to emit a red light.

However, the disclosure is not limited thereto. A center wavelength of the laser L may also be other wavelengths. The third light-emitting element 130B having the highest absorption rate for the laser L, the second light-emitting element 130G having the medium absorption rate for the laser L, and the first light-emitting element 130R having the lowest absorption rate for the laser L may also be light-emitting elements used to emit other color lights. In another embodiment, the center wavelength of the laser L may also be 405 nm. The third light-emitting element 130B having the highest absorption rate for the laser L may be a light-emitting element used to emit a red light. The second light-emitting element 130G having the medium absorption rate for the laser L may be a light-emitting element used to emit a green light. The first light-emitting element 130R having the lowest absorption rate for the laser L may be a light-emitting element used to emit a blue light.

Referring to FIG. 2, in some embodiments, the plurality of pixel structures PX may include a repaired pixel structure PXr. The plurality of light-emitting elements 130 of the repaired pixel structure PXr include a normal light-emitting element 130n and a repairing light-emitting element 130r. A distance D4 between the repairing light-emitting element 130r and the first metal element 162 is greater than a distance D3 between the normal light-emitting element 130n and the first metal element 162. That is, in a manufacturing process of the display apparatus 10, when the plurality of light-emitting elements 130 are first transferred, the light-emitting element 130 is disposed at an end of the pad group 120 that is closer to the first metal element 162. When the display apparatus 10 is repaired, the repairing light-emitting element 130r is preferably disposed at another end of the pad group 120 that is farther from the first metal element 162.

What is claimed is:

1. A display apparatus, comprising:
a substrate; and
a plurality of pixel structures disposed on the substrate, wherein each of the plurality of pixel structures comprises:
a plurality of pad groups, wherein each of the plurality of pad groups comprises at least one pad;
a plurality of light-emitting elements respectively bonded to the plurality of pad groups; and
a first metal element and a second metal element disposed outside the plurality of pad groups and staggered with each other, wherein a line width of the first metal element is greater than a line width of the second metal element, the first metal element extends in a first direction, and a long side of the at least one pad intersects with the first direction.

2. The display apparatus according to claim 1, wherein the long side of the at least one pad is substantially parallel to the second metal element.

3. The display apparatus according to claim 1, wherein the second metal element extends in a second direction, the first direction intersects with the second direction, the at least one pad of each of the plurality of pad groups comprises a first pad and a second pad, a geometric center of the first pad has a first distance from the first metal element in the second direction, a geometric center of the second pad has a second distance from the first metal element in the second direction, and a difference value between the first distance and the second distance is less than a width of the first pad in the first direction.

4. The display apparatus according to claim 1, wherein the plurality of light-emitting elements comprise a first light-emitting element and a second light-emitting element, an absorption rate of the second light-emitting element for a laser is greater than an absorption rate of the first light-emitting element for the laser, and the second light-emitting element is farther from an intersection of the first metal element and the second metal element than the first light-emitting element.

5. The display apparatus according to claim 4, wherein the plurality of light-emitting elements further comprise a third light-emitting element, an absorption rate of the third light-emitting element for the laser is greater than the absorption rate of the second light-emitting element for the laser, and the third light-emitting element is farther from the intersection of the first metal element and the second metal element than the second light-emitting element.

6. The display apparatus according to claim 1, wherein the plurality of light-emitting elements comprise a first light-emitting element and a second light-emitting element, the first light-emitting element is configured to emit a red light, the second light-emitting element is configured to emit a green light, and the second light-emitting element is farther from an intersection of the first metal element and the second metal element than the first light-emitting element.

7. The display apparatus according to claim 6, wherein the plurality of light-emitting elements further comprise a third light-emitting element, the third light-emitting element is configured to emit a blue light, and the third light-emitting element is farther from the intersection of the first metal element and the second metal element than the second light-emitting element.

8. The display apparatus according to claim 1, wherein the second metal element extends in a second direction, the first direction intersects with the second direction, the plurality of pixel structures comprise a repaired pixel structure, a plurality of light-emitting elements of the repaired pixel structure comprise at least one normal light-emitting element and at least one repairing light-emitting element, and a distance between the at least one repairing light-emitting element and the first metal element is greater than a distance between the at least one normal light-emitting element and the first metal element.

9. A display apparatus, comprising:
a substrate; and
a plurality of pixel structures disposed on the substrate, wherein each of the plurality of pixel structures comprises:
a plurality of pad groups, wherein each of the plurality of pad groups comprises a first pad and a second pad;
a plurality of light-emitting elements respectively bonded to the plurality of pad groups;
a first metal element and a second metal element disposed outside the plurality of pad groups and staggered with each other, wherein a line width of the first metal element is greater than a line width of the second metal element, the first metal element extends in a first direction, the second metal element extends in a second direction, the first direction intersects with the second direction, a geometric center of the first pad has a first distance from the first metal element in the second direction, a geometric center of the second pad has a second distance from the first metal element in the second direction, and a difference value between the first distance and the second distance is less than a width of the first pad in the first direction.

10. The display apparatus according to claim 9, the plurality of light-emitting elements comprise a first light-emitting element and a second light-emitting element, an absorption rate of the second light-emitting element for a laser is greater than an absorption rate of the first light-emitting element for the laser, and the second light-emitting element is farther from an intersection of the first metal element and the second metal element than the first light-emitting element.

11. The display apparatus according to claim 10, wherein the plurality of light-emitting elements further comprise a third light-emitting element, an absorption rate of the third light-emitting element for the laser is greater than the absorption rate of the second light-emitting element for the laser, and the third light-emitting element is farther from the intersection of the first metal element and the second metal element than the second light-emitting element.

12. The display apparatus according to claim 9, wherein the plurality of light-emitting elements comprise a first light-emitting element and a second light-emitting element, the first light-emitting element is configured to emit a red light, the second light-emitting element is configured to emit a green light, and the second light-emitting element is farther from an intersection of the first metal element and the second metal element than the first light-emitting element.

13. The display apparatus according to claim 12, wherein the plurality of light-emitting elements further comprise a third light-emitting element, the third light-emitting element is configured to emit a blue light, and the third light-emitting element is farther from the intersection of the first metal element and the second metal element than the second light-emitting element.

14. The display apparatus according to claim 9, wherein the plurality of pixel structures comprise a repaired pixel structure, a plurality of light-emitting elements of the repaired pixel structure comprise at least one normal light-emitting element and at least one repairing light-emitting element, and a distance between the at least one repairing light-emitting element and the first metal element is greater than a distance between the at least one normal light-emitting element and the first metal element.

15. The display apparatus according to claim 9, wherein the long side of the first pad is substantially parallel to the second metal element.
